(19) United States
(12) Patent Application Publication
(10) Pub. No.: US 2002/0047148 A1
(43) Pub. Date: Apr. 25, 2002

(54) Methods of manufacturing integrated circuit capacitors having ruthenium upper electrodes and capacitors formed thereby

(76) Inventors: Seok-Jun Won, Seoul (KR); Cha-young Yoo, Seoul (KR); Young-wook Park, Kyungki-do (KR)

Correspondence Address: MYERS BIGEL SIBLEY & SAJOVEC, PO BOX 37428, RALEIGH, NC, 27627, US

(21) Appl. No.: 09/899,867

(22) Filed: Jul. 5, 2001

(30) Foreign Application Priority Data
Jul. 6, 2000 (KR) 2000-38593
Jun. 29, 2001 (KR) 2001-38160

(51) Int. Cl. H01L 29/94

(52) U.S. Cl. 257/296

(57) ABSTRACT

Methods of manufacturing integrated circuit capacitors having low equivalent oxide thickness (Toxeq) and excellent leakage current characteristics include forming a lower capacitor electrode on a semiconductor substrate and then forming a capacitor dielectric layer on the lower capacitor electrode. An upper capacitor electrode, comprising ruthenium (Ru), is then formed on the capacitor dielectric layer. The step of forming an upper capacitor electrode is preceded by the step of heat treating the metal oxide dielectric layer in an oxygen containing ambient at a temperature in a range between about 100° C. and about 600° C. This heat treatment step is preferably performed in order to incorporate additional quantities of oxygen into the metal oxide dielectric layer, so that the metal oxide dielectric layer is enriched with oxygen.

### RELATED APPLICATION

This application claims priority to Korean Application No. 2000-38593, filed Jul. 6, 2000, and to Korean Application No. 2001-38160 filed Jun. 29, 2001, the disclosures of which are hereby incorporated herein by reference.

1. Field of the Invention

The present invention relates to methods of manufacturing semiconductor devices, and more particularly, to methods of manufacturing integrated circuit capacitors.

1. Background of the Invention

As the integration density of semiconductor memory devices increases, memory cell area decreases. A reduction in cell capacitance is a serious obstacle to increasing the integration of memory devices, including dynamic random access memory (DRAM) devices. The reduction in cell capacitance not only typically lowers the read capability of the memory cell and typically increases an error rate in software, but also makes the operation of the device more difficult at low voltages. Power consumption may also be excessive when operating such memory devices. Accordingly, methods of increasing cell capacitance should be developed so that very high integration semiconductor memory devices can be achieved.

Methods for increasing an effective area of a capacitor include using a three-dimensional storage electrode structure, for example, a cylinder pin, using dielectric films comprising a high dielectric material, and using thin dielectric films.

Generally, the dielectric characteristic of a cell capacitor can be evaluated by evaluating the equivalent oxide thickness (Toxeq) and leakage current density. The equivalent oxide thickness is a value obtained by converting the thickness of a dielectric film (other than a silicon oxide substance) into an effective thickness of a dielectric film formed of silicon oxide. As the Toxeq value decreases, the capacitance increases. It is also preferable that the leakage current density be low in order to improve the electric characteristics of the capacitor.

According to one method of increasing cell capacitance, a high dielectric film having a high dielectric constant may be substituted for a silicon nitride film or a silicon oxide film as the dielectric film of a capacitor. A representative example is the use of a Ta₂O₅ film. When a Ta₂O₅ film is used as a dielectric film formed on a first electrode layer of a storage node and a polysilicon film is formed as a second electrode layer over the Ta₂O₅ film, then the Ta₂O₅ film comes into contact with the polysilicon film. When this contact occurs, oxygen within the Ta₂O₅ film and silicon within the polysilicon film react form SiO₂ and thereby to increase the effective oxide thickness. This increase in effective oxide thickness may cause a decrease in capacitance and may cause an increase in leakage current as the concentration of oxygen inside the Ta₂O₅ film is decreased.

To solve the above problem, a method of forming the second electrode layer, which forms the upper electrode, as a WN or TiN metal film over the high dielectric film has been suggested. However, WN metal films typically have poor step coverage. Thus, if the second electrode layer is formed of a WN film, it may be difficult to achieve a high integration semiconductor device. In the case of forming the second electrode layer as a TiN film, it may be difficult to decrease the equivalent oxide thickness (Toxeq) below 30 Å.

Thus, notwithstanding these techniques to increase capacitance using higher dielectric materials, there continues to be a need for improved methods that result in capacitors having high per unit area capacitance and excellent leakage current characteristics.

### SUMMARY OF THE INVENTION

Methods according to embodiments of the present invention provide integrated circuit capacitors having low equivalent oxide thickness (Toxeq) and excellent leakage current characteristics, using dielectric materials having relatively high dielectric constants. These integrated circuit capacitors may be used in many applications including memory device applications (e.g., DRAM devices). According to one embodiment of the present invention, a method of forming an integrated circuit capacitor includes forming a lower capacitor electrode on a semiconductor substrate and then forming a capacitor dielectric layer on the lower capacitor electrode. An upper capacitor electrode, comprising ruthenium (Ru), is then formed on the capacitor dielectric layer. According to a preferred aspect of this embodiment, the step of forming an upper capacitor electrode is preceded by the step of heat treating the metal oxide dielectric layer in an oxygen containing ambient at a temperature in a range between about 100° C. and about 600° C. This heat treatment step is preferably performed in order to incorporate additional quantities of oxygen into the metal oxide dielectric layer, so that the metal oxide dielectric layer is enriched with oxygen.

The step of forming the capacitor dielectric layer preferably comprises forming a silicon nitride layer on the lower capacitor electrode and forming a metal oxide dielectric layer on the silicon nitride layer, opposite the lower capacitor electrode. In particular, surfaces on the lower capacitor electrode are preferably exposed to a nitrogen ambient during a heat treatment step, so that the exposed surfaces are nitrided. This heat treatment step may be performed by exposing the lower capacitor electrode to an ammonia (NH₃) ambient at a temperature greater than about 600° C. Alternatively, the silicon nitride layer may be deposited using a chemical vapor deposition technique. The silicon nitride layer may have a thickness in a range between about 5 Å and about 30 Å, so that the underlying lower capacitor electrode, which may comprise a relatively easily oxidized material such as polysilicon, is not exposed to the oxygen ambient during the subsequent heat treatment of the metal oxide dielectric layer. The metal oxide dielectric layer is preferably a metal oxide selected from the group consisting of tantalum pentoxide and aluminum oxide. If a tantalum pentoxide layer is used, it preferably has a thickness in a range between about 40 Å and about 100 Å. If an aluminum oxide layer is used, it preferably has a thickness in a range between about 20 Å and about 80 Å.

The step of heat treating the metal oxide dielectric layer in an oxygen containing ambient may include heat treating the metal oxide dielectric layer in an ozone ambient, an ambient comprising UV-O₃ or exposing the metal oxide dielectric layer to an oxygen plasma. In particular, heat treating the metal oxide dielectric layer in an ozone or UV-O₃ ambient is preferably performed at a temperature in a range between about 200° C. and about 600° C. and at a pressure in a range between about 10 torr and atmospheric pressure. Alternatively, heat treating the metal oxide dielectric layer in an oxygen plasma is performed at a temperature in a range between about 100° C. and about 400° C. and at a pressure in a range between about 0.1 torr and 10 torr. According to another preferred aspect of the present invention, the step of heat treating the metal oxide dielectric layer in an oxygen containing ambient is followed by the step of heat treating the metal oxide dielectric layer at a temperature in a range between about 500° C. and about 850° C. and in an inert ambient comprising nitrogen gas (N₂) and/or argon gas (Ar), prior to forming the upper capacitor electrode. The leakage current characteristics can also be improved by sputtering the upper capacitor electrode comprising ruthenium directly on the capacitor dielectric layer.

### BRIEF DESCRIPTION OF THE DRAWINGS

FIGS. 1A through 1G are cross-sectional views of intermediate structures that illustrate methods of manufacturing integrated circuit capacitors according to preferred embodiments of the present invention;

FIG. 2 is a graph comparing the leakage current characteristics for integrated circuit capacitors manufactured according to an embodiment of the present invention and comparative integrated circuit capacitors;

FIG. 3 is a graph illustrating leakage current density characteristics of capacitors manufactured according to embodiments of the present invention;

FIG. 4A is a graph illustrating leakage current density characteristics of integrated circuit capacitors manufactured according to embodiments of the present invention, when an Ru film formed by a sputtering method is employed as a second electrode layer; and

FIG. 4B is a graph illustrating the leakage current density characteristics of integrated circuit capacitors manufactured according to embodiments of the present invention, when an Ru film manufactured by a chemical vapor deposition (CVD) method is employed as the second electrode layer.

FIGS. 5A-5D are graphs that illustrate leakage current characteristics of capacitors formed in accordance with embodiments of the present invention against sample capacitors.

### DESCRIPTION OF PREFERRED EMBODIMENTS

The present invention now will be described more fully with reference to the accompanying drawings, in which a preferred embodiment of the invention is shown. This invention may, however, be embodied in many different forms and should not be construed as being limited to the embodiment set forth herein; rather, this embodiment is provided so that this disclosure will be thorough and complete, and will fully convey the scope of the invention to those skilled in the art. In the drawings, the thickness of layers and regions are exaggerated for clarity. It will also be understood that when a layer is referred to as being “on” another layer or substrate, it can be directly on the other layer or substrate, or intervening layers may also be present. However, when a layer is referred to as being “directly on” another layer or substrate, it contacts the other layer or substrate and no intervening layers are present. Like numbers refer to like elements throughout.

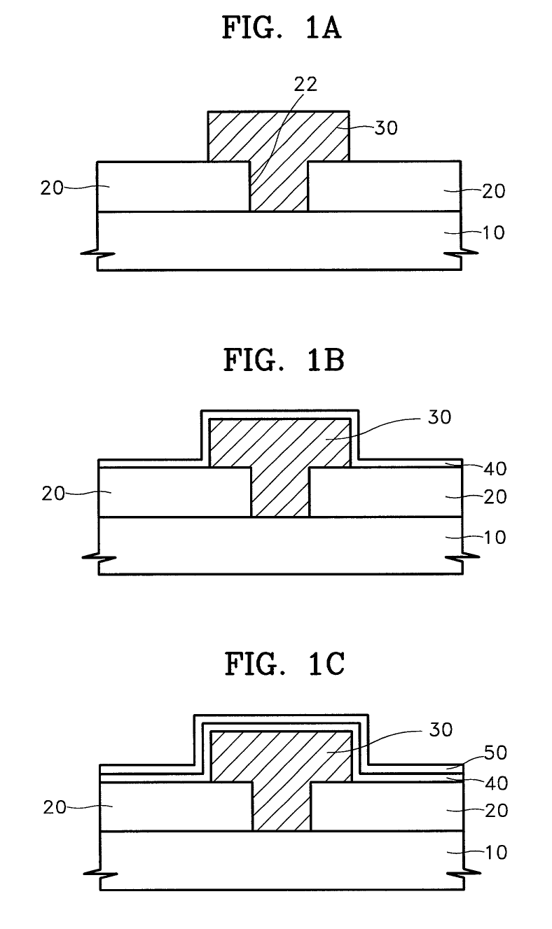

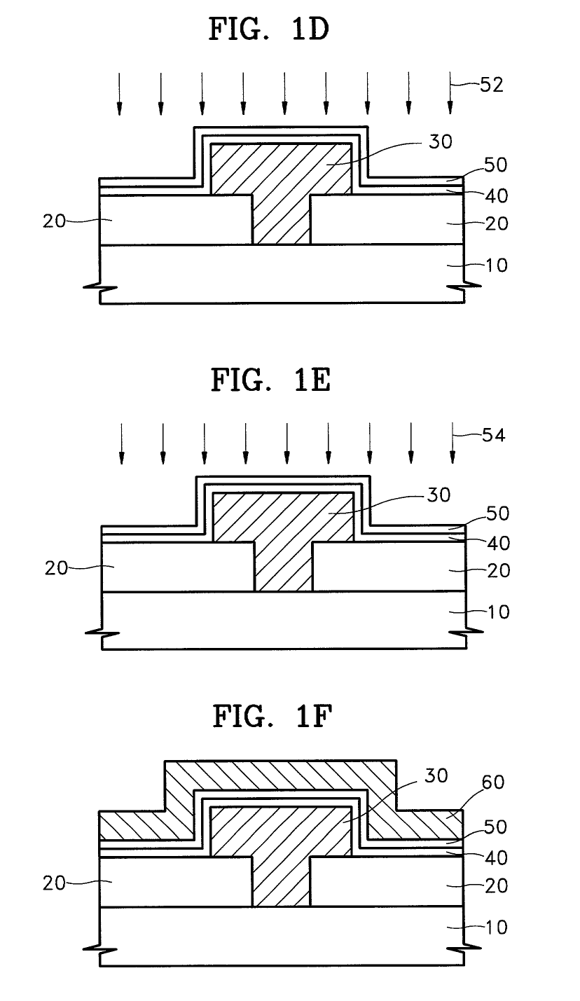

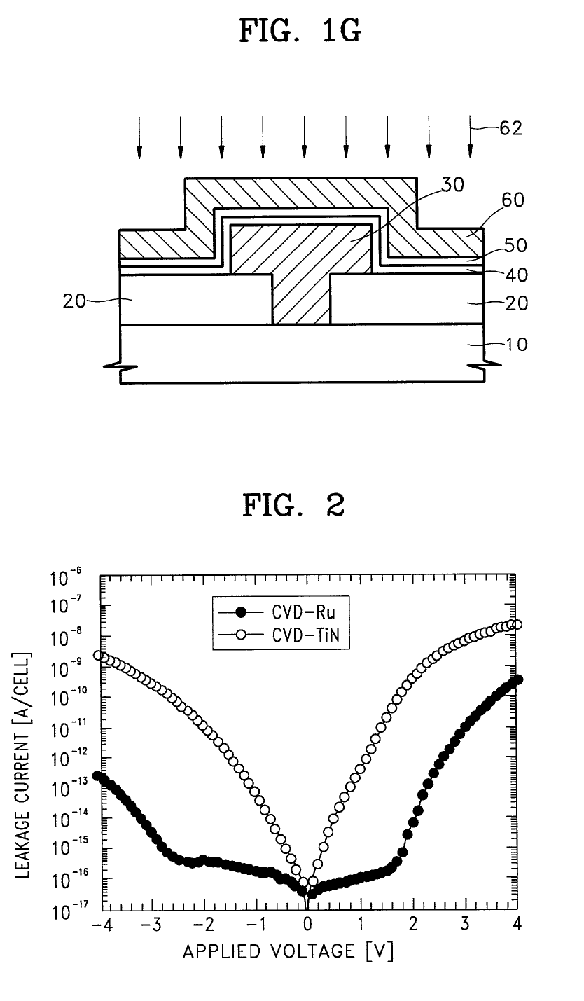

FIGS. 1A through 1G are sectional views of intermediate structures that illustrate methods of manufacturing integrated circuit capacitors according to embodiments of the present invention. Referring to FIG. 1A, after forming a dielectric layer over a semiconductor substrate 10, the dielectric layer is patterned to form an interlayer insulating film 20 having a contact hole 22 therein that exposes a portion of the semiconductor substrate 10. The exposed portion of the semiconductor substrate may constitute a source/drain region of a DRAM access transistor, for example. Following this, a polysilicon film doped with impurities is deposited inside of the contact hole 22 and on the interlayer insulating film 20. Other materials besides polysilicon may be used. The polysilicon film is patterned to form a first electrode layer 30 which constitutes a lower electrode of a capacitor.

Referring to FIG. 1B, a silicon nitride film 40 is formed to cover an exposed portion of the first electrode layer 30. The reason for forming the silicon nitride film 40 is to prevent the equivalent oxide thickness (Toxeq) of a subsequently formed capacitor from increasing due to the oxidation of the first electrode layer 30, which may comprise polysilicon, in a subsequent process step(s). To form the silicon nitride film 40, the structure having the first electrode layer 30 thereon may be heat-treated in an atmosphere of ammonia (NH₃) so as to nitride the exposed surface of the first electrode layer 30. This heat-treatment step may be performed at a temperature of greater than about 600° C. Alternatively, a Si₃N₄ film may be deposited by CVD to form the silicon nitride film 40. Preferably, the silicon nitride film 40 is formed to a thickness of about 5-30 Å. Other oxidation inhibiting materials may be used instead of (or in addition to) the silicon nitride film 40.

Referring now to FIG. 1C, a dielectric film 50 having a high dielectric constant is formed over the entire surface of the silicon nitride film 40. Preferably, the dielectric film 50 is formed of a high dielectric material such as Ta₂O₅ or Al₂O₃. Other high dielectric materials may also be used. In the event the dielectric film 50 is Ta₂O₅, it is preferable that its thickness be about 40-100 Å. In the event the dielectric film 50 is Al₂O₃, it is preferable that its thickness be about 20-80 Å.

Referring now to FIG. 1D, the dielectric film 50 is first heat-treated in an oxygen-containing atmosphere 52 at a temperature in a range between about 100° C. and about 600° C. This first heat-treatment step is performed to decrease leakage current in the capacitor by compensating for the loss of oxygen inside of the dielectric film 50 and also inhibiting oxidation of the first electrode layer 30. Oxidation can be inhibited by performing the heat treatment step at a relatively low temperature.

The oxygen-containing atmosphere may be established using a gas containing ozone (O₃), UV-O₃, or by establishing an oxygen (O₂) plasma. If a gas containing O₃ or UV-O₃ is used for the oxygen-containing atmosphere 52, the temperature is preferably set at a level in a range between about 200° C. and about 600° C. and the pressure is set at a level between 10 Torr and atmospheric pressure. If O₂ plasma is used for the oxygen-containing atmosphere 52, the plasma is applied at a temperature in a range between about 100° C. and about 400° C. and the pressure is set at 0.1-10 Torr.

Referring to FIG. 1E, the dielectric film 50 is then crystallized at a temperature that is preferably equal to or higher than that used for subsequent heat-treatment processes. This crystallization step is preferably performed to reduce adverse affects of subsequent high temperature heat-treatment steps in non-inert ambients. The crystallization step (i.e., second heat-treatment step) is preferably performed in an atmosphere of an inert gas 54. Preferably, the crystallization step is performed in an atmosphere of nitrogen (N₂) or argon (Ar) and at a temperature in a range between about 500° C. and about 850° C. This crystallization step may be omitted in some applications.

Referring now to FIG. 1F, a second electrode layer 60 is preferably formed of an Ru film using a sputtering method or a CVD method. The use of an Ru film as the second electrode layer 60 can assist in lowering the equivalent oxide thickness of the dielectric film 50. The use of Ruthenium (Ru) is preferred because it has a higher electric barrier height than conventional materials such as TiN or metal nitrides. Accordingly, even if the dielectric film 50 is thin, leakage currents at the interface between the second electrode layer 60 and the dielectric film 50 can be reduced.

Referring to FIG. 1G, the resultant structure having the second electrode layer 60 thereon may then be heat treated again in an oxygen-containing atmosphere 62 at a temperature in a range between about 300° C. and about 550° C. Here, the oxygen-containing atmosphere 62 can include oxygen at a concentration in a range of 1-100% by volume. The oxygen-containing atmosphere 62 may also be formed of a mixture of O₂ gas and an inert gas, for example, N₂ gas or Ar gas, and in this case, it is preferable that the concentration of oxygen is 1-10% by volume and the pressure is atmospheric pressure. If the pressure of the oxygen-containing atmosphere 62 is controlled to be equal to or less than atmospheric pressure, then the concentration of oxygen in the oxygen-containing atmosphere 62 may be higher in a range between 10-100% by volume. Gases such as O₂ gas, N₂O gas, or O₃ gas can also be used to form the oxygen-containing atmosphere 62.

During this third heat treatment step, oxygen penetrating through the Ru film forming the second electrode layer 60 can inhibit the occurrence of leakage currents at the interface between the dielectric film 50 and the second electrode layer 60, and can also repair defects in the dielectric film 50.

If the second electrode layer 60 comprising Ru is formed by a CVD method, the third heat treatment step under the oxygen-containing atmosphere, as explained with reference to FIG. 1G, can be omitted. This is because an Ru film formed by a CVD method typically already contains sufficient oxygen from the atmosphere associated with the deposition process. As a result, the second electrode layer 60 may be able to provide sufficient oxygen to the interface between the dielectric layer 50 and the second electrode layer 60, even if the third heat treatment step is omitted.

FIG. 2 is a graph comparing the leakage current characteristics of sample capacitors formed in accordance with methods of embodiments of the present invention and having a second electrode layer formed of an Ru film against comparative example capacitors having a second electrode layer formed of a TiN film. The process used to form a preferred sample capacitor includes forming the first electrode layer as a doped polysilicon layer. The first electrode layer is heat-treated with NH₃ at a temperature of 850° C. and at a pressure of 100 Torr for 60 seconds. This heat treatment step causes the surface of the first electrode layer to be nitrided so that a silicon nitride film is formed over the exposed surface of the first electrode layer. Then, using a CVD method, a dielectric film of Ta₂O₅ with a thickness of 40 Å is formed on the silicon nitride film. The Ta₂O₅ dielectric film is then heat-treated in an oxygen-containing atmosphere formed of UV-O₃ at a temperature of 300° C. and atmospheric pressure for 15 minutes. Under these heat-treatment conditions, the polysilicon within the first electrode is not subject to significant oxidation and any loss of oxygen from the Ta₂O₅ film is inhibited. The dielectric film formation process and the heat-treatment process using UV-O₃ may also be performed in sequence again to form a dielectric film having a total thickness of 80 Å. The second electrode layer, comprising Ru, is then formed to a thickness of 1000 Å by a CVD method, on the heat-treated dielectric film. The preferred capacitor (-●- CVD-Ru in FIG. 2), which was obtained by the above described process, has more stable leakage current characteristic relative to a comparative capacitor (-◯- CVD-TiN in FIG. 2) which was manufactured in accordance with the above-described steps, except that the second electrode layer was formed as a TiN film using a CVD method.

In a method of manufacturing a capacitor according to an embodiment of the present invention, after forming a dielectric film, a heat-treatment process at a high temperature of 700° C. or higher, for example, a heat-treatment step in an oxygen atmosphere using dry O₂, is not necessary. Also, more stable leakage current characteristics can be obtained using Ru as a second electrode material, instead of TiN. Also, if CVD-TiN is used for the second electrode layer, the equivalent oxide thickness (Toxeq) at which a stable leakage current of 100 nA/cm² or less can be obtained when a voltage of 1.0 V is applied across the capacitor, is 30 Å. However, a lower Toxeq thickness of 20-25 Å can be obtained with the same leakage current characteristics, by using an Ru film as the second electrode layer.

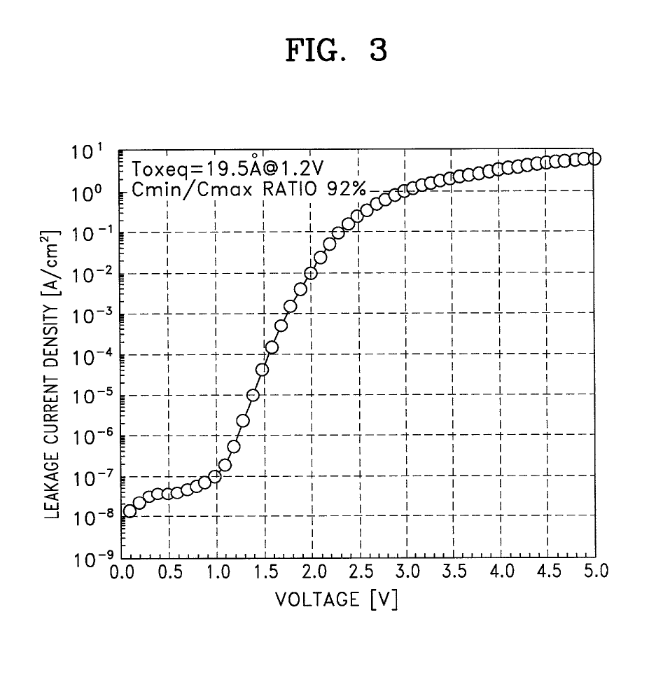

FIG. 3 is a graph illustrating the leakage current density characteristics of a capacitor manufactured in accordance with an embodiment of the present invention. A sample capacitor used to obtain the results of FIG. 3 was manufactured as will now be described. After forming the first electrode layer comprising doped polysilicon, using the same method as explained above with respect to FIGS. 1A-1G, the first electrode layer is heat-treated in an NH₃ ambient at a temperature of 850° C. and a pressure of 100 Torr for 60 seconds. This causes the surface of the first electrode layer to be nitrided. Following this, using a CVD method, a dielectric film comprising Ta₂O₅ is formed to a thickness of 60 Å on the first electrode layer, with the silicon nitride film disposed therebetween. Then, the dielectric film is heat-treated in an oxygen-containing atmosphere, formed of UV-O₃, at a temperature of 300° C. and at atmospheric pressure for 15 minutes. A second electrode layer comprising Ru is then formed on the heat-treated dielectric film using a sputtering method. The second electrode layer is formed to a thickness of 1000 Å. The second electrode layer is heat-treated in an oxygen-containing atmosphere. The oxygen containing atmosphere includes a mixture of oxygen at 5% by volume and N₂ gas. The heat treatment step is performed at a temperature of 400° C. and atmospheric pressure for 30 minutes.

As illustrated by FIG. 3, when a voltage of 1.2 V is applied across the capacitor, a Toxeq of 19.5 Å can be obtained at the 100 nA/cm² level of leakage current density. Also, the Cmin/Cmax ratio, which is the ratio between the capacitance obtained when the voltage applied across the capacitor is 1.2 V and the capacitance Cmax when the voltage applied across the capacitor is −1.2 V, has a high value of about 92%.

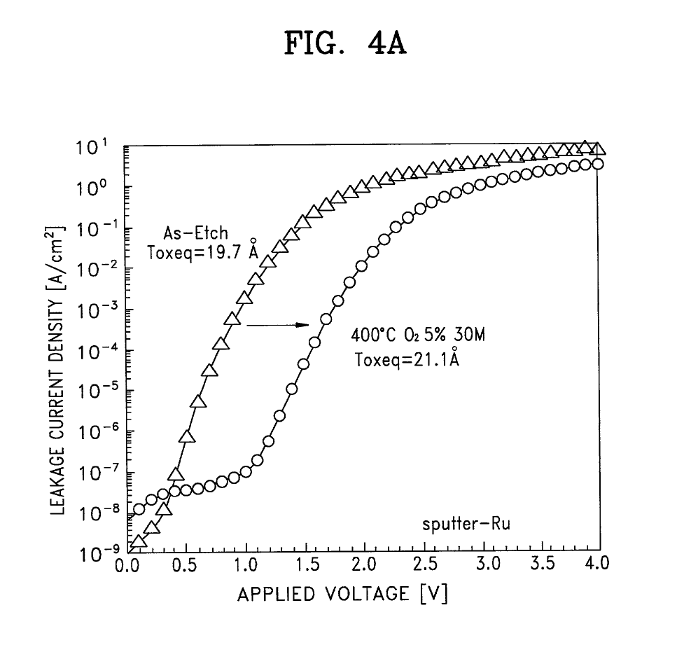

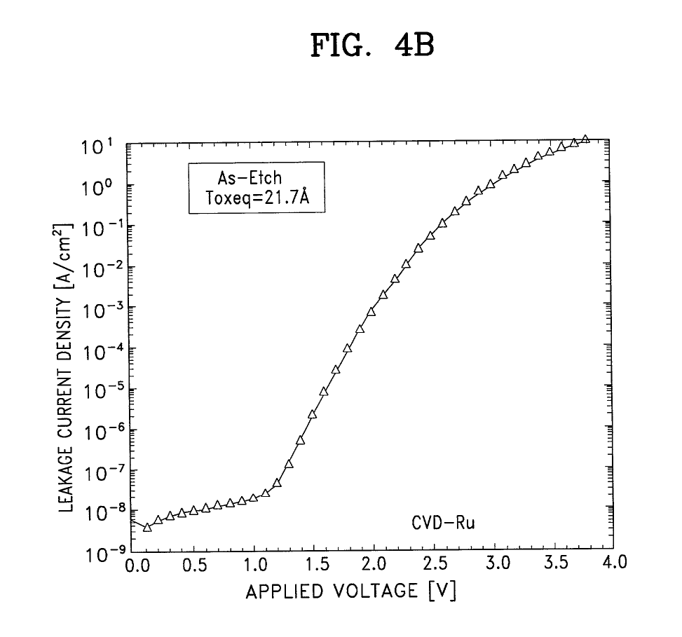

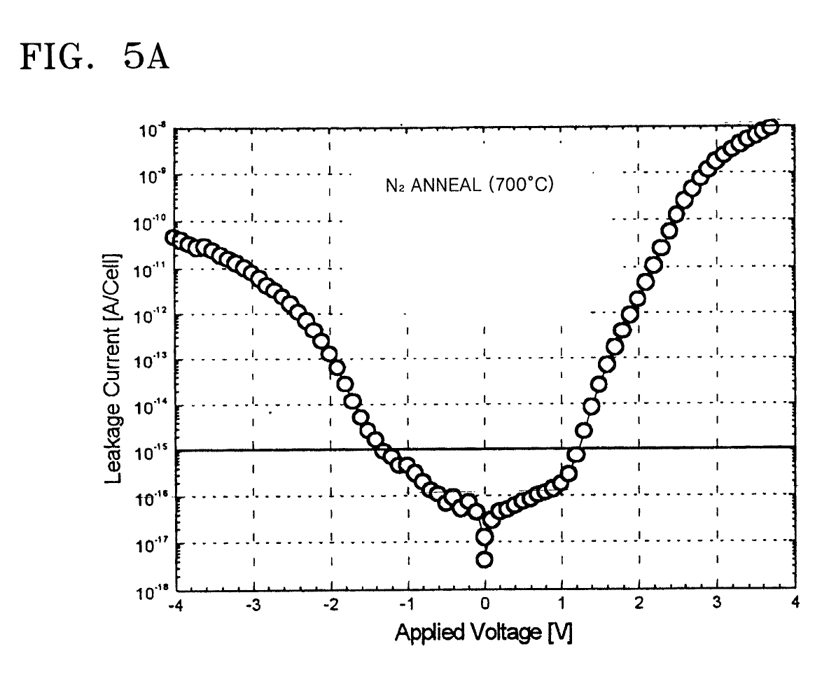

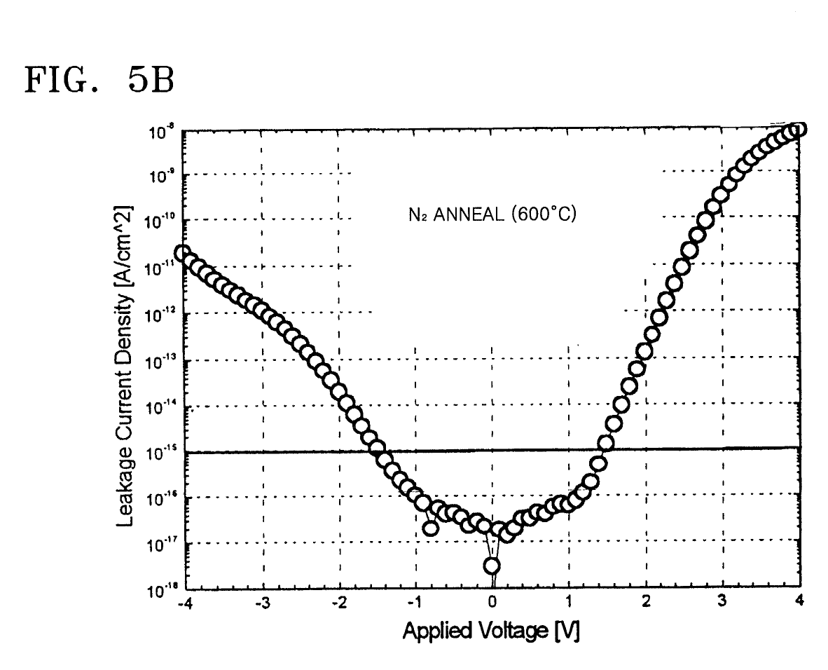

FIGS. 4A and 4B are graphs illustrating leakage current characteristics in the case of employing an Ru film formed by the preferred sputtering method (sputter-Ru) as the second electrode layer, and in the case of employing the Ru film formed by the alternative CVD method (CVD-Ru) as the second electrode layer. In FIG. 4A, the leakage current density (-Δ-), measured immediately after forming the second electrode layer as a sputter-Ru layer (by the same method described with respect to FIG. 3), is illustrated. Also, the leakage current density (-◯-), measured after heat-treating the second electrode layer under an oxygen-containing atmosphere (formed of a mixture of 5% oxygen by volume and N₂ gas) at a temperature of 400° C. and atmospheric pressure, for 30 minutes, is illustrated. In FIG. 4B, the dielectric film formation process and the subsequent heat-treatment process using UV-O₃ are performed in accordance with the corresponding steps described above with respect to FIG. 3, and then, immediately after forming the second electrode layer (comprising Ru) by a CVD method, the leakage current density (-Δ-) was measured without the heat-treatment process in an oxygen-containing atmosphere.

As shown by the results of FIGS. 4A and 4B, if an Ru film formed by a sputtering method is employed as the second electrode layer, the leakage current density characteristic is stabilized when it is heat-treated in an oxygen-containing atmosphere at a temperature in a range between about 350° C. and about 550° C. On the other hand, if a Ru film formed by a CVD method is employed as the second electrode layer, oxygen is included in the CVD process itself so that an excellent leakage current characteristic is obtained without requiring the heat-treatment process in an oxygen-containing atmosphere after forming the second electrode layer.

As described above with respect to FIG. 1E, the second heat treatment step may be a crystallization step that is performed in an ambient comprising nitrogen (N₂) and/or argon (Ar) at a temperature in a range between about 500° C. and 850° C., to reduce the adverse effects of subsequent high temperature thermal treatment steps. However, as an alternative, the second heat treatment step may be performed in an O₂ atmosphere at a relatively low temperature in a range between about 500° C. and 700° C. At this lower temperature, the dielectric film 50 may not be crystallized. Under these conditions, the dielectric film 50 consisting of Ta₂O₅ can be maintained in an amorphous state. The oxidation of the first electrode layer 30 can be more effectively inhibited when using amorphous Ta₂O₅ instead of crystalline Ta₂O₅, and thus any formation of an oxide film at the interface between the first electrode layer 30 and the dielectric film 50 can be inhibited. Accordingly, a Toxeq for the capacitor having an Ru upper electrode and an amorphous Ta₂O₅ dielectric layer can be maintained at a low level.

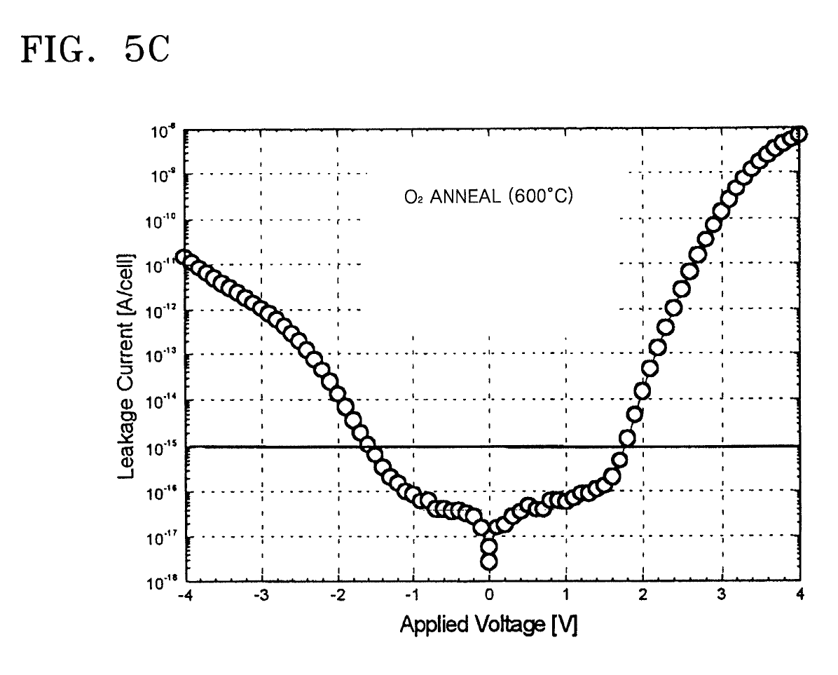

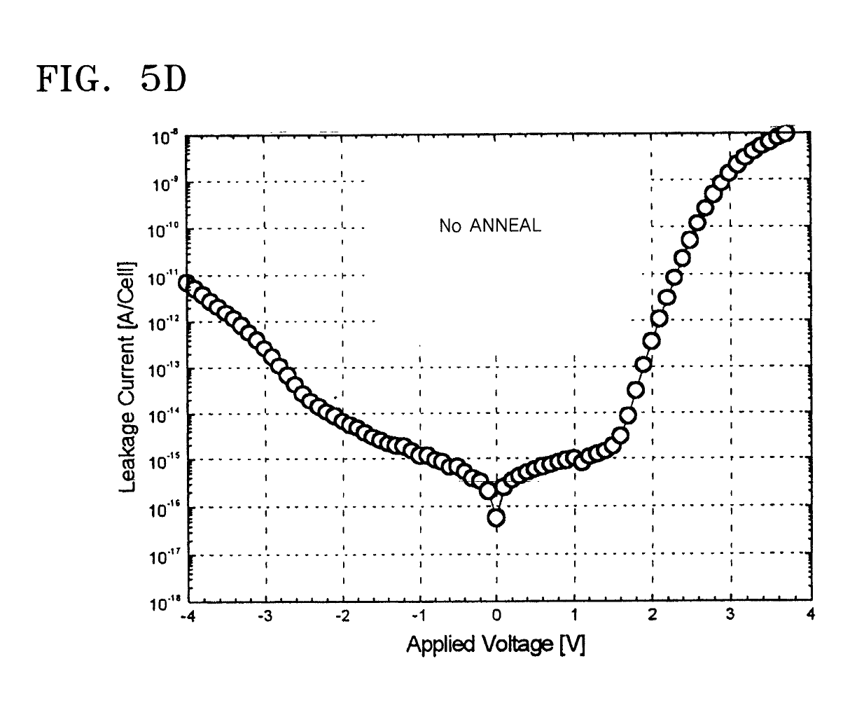

FIGS. 5A through 5D are graphs comparing the leakage current characteristics of sample capacitors formed in accordance with various methods of the embodiments of the present invention. FIGS. 5A and 5B are cases of heat-treating the dielectric film in an N₂ atmosphere as the second heat-treatment step (see, e.g., FIG. 1E). FIG. 5C is the case of heat-treating the dielectric film in an O₂ atmosphere as the second heat-treatment step, so that, as described above, an amorphous Ta₂O₅ layer can be formed. FIG. 5D is the case when the second heat-treatment step is omitted.

Specifically, the capacitor of FIG. 5A is obtained by the same method as for the CVD-Ru capacitor in FIG. 2, except that a dielectric film of Ta₂O₅ with a thickness of 60 Å is formed on a silicon nitride film after the formation of the silicon nitride film. The Ta₂O₅ dielectric film is then heat-treated in an oxygen-containing atmosphere formed of UV-O₃ at a temperature of 400° C. and atmospheric pressure for 15 minutes. The process of forming a 30 Å thick dielectric film and the heat-treatment process using UV-O₃ are performed in sequence again to form a dielectric film having a total thickness of 90 Å. The dielectric film is then heat-treated in an N₂ atmosphere at 700° C. so that the dielectric film is crystallized.

The capacitor of FIG. 5B is obtained by the same method as in FIG. 5A, except that a dielectric film of Ta₂O₅ with a thickness of 60 Å is formed on a silicon nitride film after the formation of the silicon nitride film. The Ta₂O₅ dielectric film is then heat-treated in an oxygen-containing atmosphere formed of UV-O₃ at a temperature of 400° C. and atmospheric pressure for 15 minutes. The Ta₂O₅ dielectric film having a thickness of 60 Å is then heat-treated in an N₂ atmosphere at 600° C. so that the Ta₂O₅ dielectric film is maintained in an amorphous state. The capacitor of FIG. 5C is obtained by the same method as in FIG. 5B, except that a dielectric film of Ta₂O₅ with a thickness of 60 Å is formed on a silicon nitride film after the formation of the silicon nitride film. The Ta₂O₅ dielectric film is then heat-treated in an oxygen-containing atmosphere formed of UV-O₃ at a temperature of 400° C. and atmospheric pressure for 15 minutes. The Ta₂O₅ dielectric film having a thickness of 60 Å is then heat-treated in an O₂ atmosphere at 600° C. so that the Ta₂O₅ dielectric film is maintained in an amorphous state. The capacitor of FIG. 5D is obtained by the same method as in FIG. 5C, except that the second heat-treatment is omitted after a Ta₂O₅ dielectric film having a thickness of 60 Å is obtained. In the capacitors of FIGS. 5A through 5D, Toxeq values of 25.3 Å, 26 Å, 26.8 Å, and 24 Å are obtained, respectively. Each of the capacitors of FIGS. 5A through 5C has stable leakage current characteristics. The capacitor of FIG. 5D, which did not undergo the second heat-treatment in an N₂ or O₂ atmosphere, has less stable leaking current characteristics at a low level of applied voltage when compared with the capacitors of FIGS. 5A through 5C.

In the drawings and specification, there have been disclosed typical preferred embodiments of the invention and, although specific terms are employed, they are used in a generic and descriptive sense only and not for purposes of limitation, the scope of the invention being set forth in the following claims.

That which is claimed is:

1. A method of forming an integrated circuit capacitor, comprising the steps of:
forming a lower capacitor electrode on a semiconductor substrate;
forming a capacitor dielectric layer on the lower capacitor electrode; and
forming an upper capacitor electrode comprising ruthenium (Ru) on the capacitor dielectric layer.

2. The method of claim 1, wherein said step of forming a capacitor dielectric layer comprises the steps of:
forming a silicon nitride layer on the lower capacitor electrode; and
forming a metal oxide dielectric layer on the silicon nitride layer, opposite the lower capacitor electrode.

3. The method of claim 2, wherein the lower capacitor electrode comprises polysilicon; and wherein said step of forming a silicon nitride layer comprises forming a silicon nitride layer directly on the lower capacitor electrode.

4. The method of claim 3, wherein said step of forming a silicon nitride layer comprises heat treating the lower capacitor electrode in an ammonia (NH₃) ambient at a temperature greater than about 600° C.

5. The method of claim 2, wherein said step of forming an upper capacitor electrode is preceded by the step of heat treating the metal oxide dielectric layer in an oxygen containing ambient at a temperature in a range between about 100° C. and about 600° C.

6. The method of claim 3, wherein said step of forming an upper capacitor electrode is preceded by the step of heat treating the metal oxide dielectric layer in an oxygen containing ambient at a temperature in a range between about 100° C. and about 600° C.

7. The method of claim 4, wherein said step of forming an upper capacitor electrode is preceded by the step of heat treating the metal oxide dielectric layer in an oxygen containing ambient at a temperature in a range between about 100° C. and about 600° C.

8. The method of claim 3, wherein said step of forming a silicon nitride layer comprises depositing a silicon nitride layer on the lower capacitor electrode by chemical vapor deposition.

9. The method of claim 3, wherein the silicon nitride layer has a thickness in a range between about 5 Å and about 30 Å.

10. The method of claim 2, wherein the metal oxide dielectric layer is a metal oxide selected from the group consisting of tantalum pentoxide and aluminum oxide.

11. The method of claim 10, wherein the metal oxide dielectric layer is a tantalum pentoxide layer having a thickness in a range between about 40 Å and about 100 Å.

12. The method of claim 10, wherein the metal oxide dielectric layer is an aluminum oxide layer having a thickness in a range between about 20 Å and about 80 Å.

13. The method of claim 5, wherein said step of heat treating the metal oxide dielectric layer in an oxygen containing ambient comprises heat treating the metal oxide dielectric layer in an ozone ambient, an ambient comprising UV-O₃ or exposing the metal oxide dielectric layer to an oxygen plasma.

14. The method of claim 5, wherein said step of heat treating the metal oxide dielectric layer in an oxygen containing ambient comprises heat treating the metal oxide dielectric layer in an ozone or UV-O₃ ambient at a temperature in a range between about 200° C. and about 600° C. and at a pressure in a range between about 10 torr and atmospheric pressure.

15. The method of claim 5, wherein said step of heat treating the metal oxide dielectric layer in an oxygen containing ambient comprises exposing the metal oxide dielectric layer to an oxygen plasma at a temperature in a range between about 100° C. and about 400° C. and at a pressure in a range between about 0.1 torr and 10 torr.

16. The method of claim 5, wherein said step of heat treating the metal oxide dielectric layer in an oxygen containing ambient is followed by the step of heat treating the metal oxide dielectric layer at a temperature in a range between about 500° C. and about 850° C. and in an inert ambient comprising nitrogen gas (N₂) and/or argon gas (Ar), prior to forming the upper capacitor electrode.

17. The method of claim 5, wherein the following step is performed between said step of heat treating the metal oxide dielectric layer in an oxygen containing ambient and said step of forming the upper capacitor electrode:
heat treating the metal oxide dielectric layer at a temperature in a range between about 500° C. and about 700° C. and in an O₂ atmosphere.

18. The method of claim 1, wherein said step of forming an upper capacitor electrode comprises forming a ruthenium layer directly on the capacitor dielectric layer by sputtering or chemical vapor deposition.

19. The method of claim 1, wherein said step of forming an upper capacitor electrode is followed by the step of heat treating the upper capacitor electrode at a temperature in a range between about 300° C. and about 550° C. in an oxygen ambient.

20. The method of claim 1, wherein said step of forming an upper capacitor electrode is followed by the step of heat treating the upper capacitor electrode at a temperature in a range between about 300° C. and about 550° C. in an ambient containing an inert gas selected from the group consisting of nitrogen gas (N₂) and argon gas (Ar), and oxygen in a range between about 1% and 10% by volume.

21. The method of claim 16, wherein said step of forming an upper capacitor electrode comprises forming a ruthenium layer directly on the capacitor dielectric layer by sputtering or chemical vapor deposition.

22. The method of claim 16, wherein said step of forming an upper capacitor electrode is followed by the step of heat treating the upper capacitor electrode at a temperature in a range between about 300° C. and about 550° C. in an oxygen ambient.

23. The method of claim 16, wherein said step of forming an upper capacitor electrode is followed by the step of heat treating the upper capacitor electrode at a temperature in a range between about 300° C. and about 550° C. in an ambient containing an inert gas selected from the group consisting of nitrogen gas (N₂) and argon gas (Ar), and oxygen in a range between about 1% and 10% by volume.

24. The method of claim 14, wherein said step of forming an upper capacitor electrode comprises forming a ruthenium layer directly on the capacitor dielectric layer by sputtering or chemical vapor deposition.

25. The method of claim 14, wherein said step of forming an upper capacitor electrode is followed by the step of heat treating the upper capacitor electrode at a temperature in a range between about 300° C. and about 550° C. in an oxygen ambient.

26. The method of claim 14, wherein said step of forming an upper capacitor electrode is followed by the step of heat treating the upper capacitor electrode at a temperature in a range between about 300° C. and about 550° C. in an ambient containing an inert gas selected from the group consisting of nitrogen gas (N₂) and argon gas (Ar), and oxygen in a range between about 1% and 10% by volume.

27. The method of claim 15, wherein said step of forming an upper capacitor electrode comprises forming a ruthenium layer directly on the capacitor dielectric layer by sputtering or chemical vapor deposition.

28. The method of claim 15, wherein said step of forming an upper capacitor electrode is followed by the step of heat treating the upper capacitor electrode at a temperature in a range between about 300° C. and about 550° C. in an oxygen ambient.

29. The method of claim 15, wherein said step of forming an upper capacitor electrode is followed by the step of heat treating the upper capacitor electrode at a temperature in a range between about 300° C. and about 550° C. in an ambient containing an inert gas selected from the group consisting of nitrogen gas (N₂) and argon gas (Ar), and oxygen in a range between about 1% and 10% by volume.

30. A method of forming an integrated circuit capacitor, comprising the steps of:
forming an electrically insulating layer having a contact hole therein, on a semiconductor substrate;
forming a lower capacitor electrode comprising polysilicon on the electrically insulating layer and in the contact hole;
encapsulating the lower capacitor electrode in a silicon nitride layer that directly contacts the lower capacitor electrode;
forming a capacitor dielectric layer comprising a metal oxide, on the silicon nitride layer; and
heat treating the capacitor dielectric layer in an oxygen ambient; and then
forming an upper capacitor electrode comprising ruthenium metal, on the capacitor dielectric layer.

31. An integrated circuit capacitor, comprising:
a semiconductor substrate;
an interlayer dielectric layer on said semiconductor substrate;
a lower capacitor electrode comprising polycrystalline silicon on said interlayer dielectric layer;
a silicon nitride layer that extends directly on an upper surface and sidewalls of said lower capacitor electrode;
a metal oxide dielectric layer on said silicon nitride layer;
an upper capacitor electrode comprising Ruthenium, on said metal oxide dielectric layer.

32. The capacitor of claim 31, wherein said metal oxide dielectric layer comprises a metal oxide selected from the group consisting of tantalum pentoxide and aluminum oxide.

33. An integrated circuit capacitor, comprising:
a semiconductor substrate;
an interlayer dielectric layer on said semiconductor substrate;
a lower capacitor electrode comprising polycrystalline silicon on said interlayer dielectric layer;
a silicon nitride layer that extends directly on an upper surface and sidewalls of said lower capacitor electrode;
an amorphous tantalum pentoxide layer on said silicon nitride layer;
an upper capacitor electrode comprising Ruthenium, on said amorphous tantalum pentoxide layer.
